(19) United States
(12) Patent Application Publication
(10) Pub. No.: US 2004/0164291 A1
(43) Pub. Date: Aug. 26, 2004

(54) Nanoelectrical compositions

(76) Inventors: Xingwu Wang, Wellsville, NY (US); Ronald Miller, Kintersville, PA (US); Howard J. Greenwald, East Rochester, NY (US)

Correspondence Address: HOWARD J. GREENWALD P.C., 349 W. COMMERCIAL STREET SUITE 2490, EAST ROCHESTER, NY, 14445-2408, US

(21) Appl. No.: 10/747,472

(22) Filed: Dec. 29, 2003

Related U.S. Application Data
(63) Continuation-in-part of application No. 10/409,505, filed on Apr. 8, 2003.
Application No. 10/409,505 is a continuation-in-part of application No. 10/324,773, filed on Dec. 18, 2002.

(51) Int. Cl. H01L 29/06

(52) U.S. Cl. 257/14

(57) ABSTRACT

A nanoelectrical material with an average particle size of less than 100 nanometers, a surface area to volume ratio of from about 0.1 to about 0.05 l/nanometer, and a relative dielectric constant of less than about 1.5.

### REFERENCE TO RELATED PATENT APPLICATIONS

This patent application is a continuation-in-part of applicants' copending patent application U.S. Ser. No. 10/409,505, filed on Apr. 8, 2003, which in turn was a continuation-in-part of applicants' copending patent application U.S. Ser. No. 10/324,773, filed on Dec. 18, 2002.

### FIELD OF THE INVENTION

A substrate coated with nanoelectrical material, wherein the nanoelectrical material has a relative dielectric constant of less than about 1.5.

### BACKGROUND OF THE INVENTION

In applicants' International patent publication WO 03/061755, certain nanomagnetic materials were disclosed. This publication was based upon International application number PCT/US03/01671, filed on Jan. 21, 2003. The entire disclosure of this International patent publication and the International application are hereby incorporated by reference into this specification.

Applicants' prior patent publications did not disclose nanoelectrical materials with low dielectric constants. It is an object of this invention to disclose such a nanoelectrical material.

### SUMMARY OF THE INVENTION

In accordance with this invention, there is provided a nanoelectrical material with an average particle size of less than 100 nanometers, a surface area to volume ratio of from about 0.1 to about 0.05 l/nanometer, and a relative dielectric constant of less than about 1.5.

### BRIEF DESCRIPTION OF THE DRAWINGS

The invention will be described by reference to the following drawings, in which like numerals refer to like elements, and in which:

FIG. 1 is phase diagram illustrating the composition of the preferred nanoelectrical materials of the invention;

FIG. 2 is a schematic illustration of one preferred process of making the coated substrate of the invention;

FIG. 3 is a sectional view of a sensor assembly;

FIGS. 4A and 4B are schematic illustrations of a process for preparing the sensor assembly of FIG. 3;

FIG. 5 is a schematic representation of a film with a specified orientation;

FIG. 6 is schematic illustration of a preferred process of the invention;

FIG. 7 is a schematic of another process of the invention;

FIG. 8 is a schematic illustration of yet another process of the invention; and

FIG. 9 is a schematic of a preferred deposition system.

### DESCRIPTION OF THE PREFERRED EMBODIMENTS

The nanoelectrical particles of this invention have an average particle size of less than about 100 nanometers. In one embodiment, such particles have an average particle size of less than about 50 nanometers. In yet another embodiment, such particles have an average particle size of less than about 10 nanometers.

The nanoelectrical particles of this invention have surface area to volume ratio of from about 0.1 to about 0.05 l/nanometer.

When the nanoelectrical particles of this invention are agglomerated into a cluster, or when they are deposited onto a substrate, the collection of particles preferably has a relative dielectric constant of less than about 1.5. In one embodiment, such relative dielectric constant is less than about 1.2.

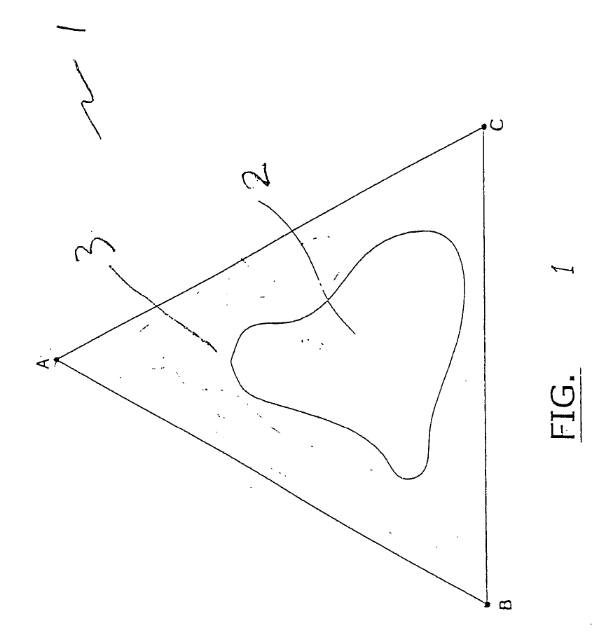

In one embodiment, the nanoelectrical particles of this invention are preferably comprised of aluminum, magnesium, and nitrogen atoms. This embodiment is illustrated in FIG. 1.

FIG. 1 illustrates a phase diagram 1 comprised of moieties A, B, and C. Moiety A is preferably selected from the group consisting of aluminum, copper, gold, silver, and mixtures thereof. It is preferred that the moiety A have a resistivity of from about 2 to about 100 microohm-centimeters. In one preferred embodiment, A is aluminum with a resistivity of about 2.824 microohm-centimeters. As will apparent, other materials with resistivities within the desired range also may be used.

Referring again to FIG. 1, C is selected from the group consisting of nitrogen and oxygen. It is preferred that C be nitrogen, and A is aluminum; and aluminum nitride is present as a phase in system.

Referring again to FIG. 1, B is preferably a dopant that is present in a minor amount in the preferred aluminum nitride. In general, less than about 50 percent (by weight) of the B moiety is present, by total weight of the doped aluminum nitride. In one aspect of this embodiment, less than about 10 weight percent of the B moiety is present, by total weight of the doped aluminum nitride.

The B moiety may be, e.g., magnesium, zinc, tin, indium, gallium, niobium, zirconium, strontium, lanthanum, tungsten, mixtures thereof, and the like. In one embodiment, B is selected from the group consisting of magnesium, zinc, tin, and indium. In another especially preferred embodiment, the B moiety is magnesium.

Referring again to FIG. 1, and when A is aluminum, B is magnesium, and C is nitrogen, it will be seen that regions 2 and 3 correspond to materials which have a low relative dielectric constant (less than about 1.5), and a high relative dielectric constant (greater than about 1.5), respectively.

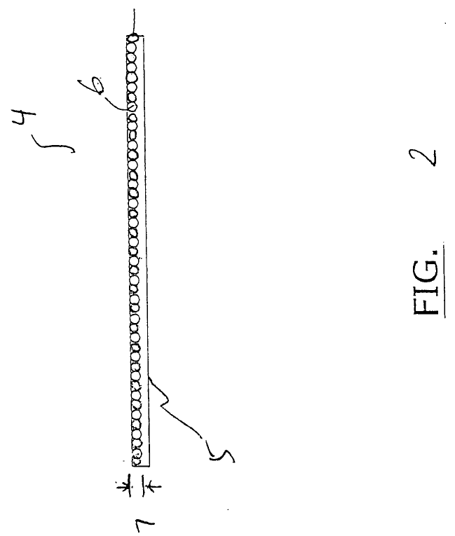

FIG. 2 is a schematic view of a coated substrate 4 comprised of a substrate 5 and a multiplicity of nanoelectrical particles 6. In this embodiment, it is preferred that the nanoelectrical particles 6 form a film with a thickness 7 of from about 10 nanometers to about 2 micrometers and, more preferably, from about 100 nanometers to about 1 micrometer.

The description of the remaining Figures is related to technology that is disclosed in U.S. Pat. No. 6,329,305, the entire disclosure of which is hereby incorporated by reference in to this specification.

Such U.S. Pat. No. 6,329,305, in its Column 1, refers to a pending patent application U.S. Ser. No. 09/503,225, for a “Method for Producing Piezoelectric Films . . . ” The entire disclosure of such pending patent application is hereby incorporated by reference into this application. Applicant Ronald Miller was, and is, a coinventor of U.S. Ser. No. 09/503,225.

Such U.S. Pat. No. 6,329,305, in its Column 1, also refers to pending patent application U.S. Ser. No. 09/145,323, filed on Sep. 1, 1998, for a “Pulsed DC Reactive Sputtering Method . . . ;” the entire disclosure of such pending application is also hereby incorporated by reference into this application.

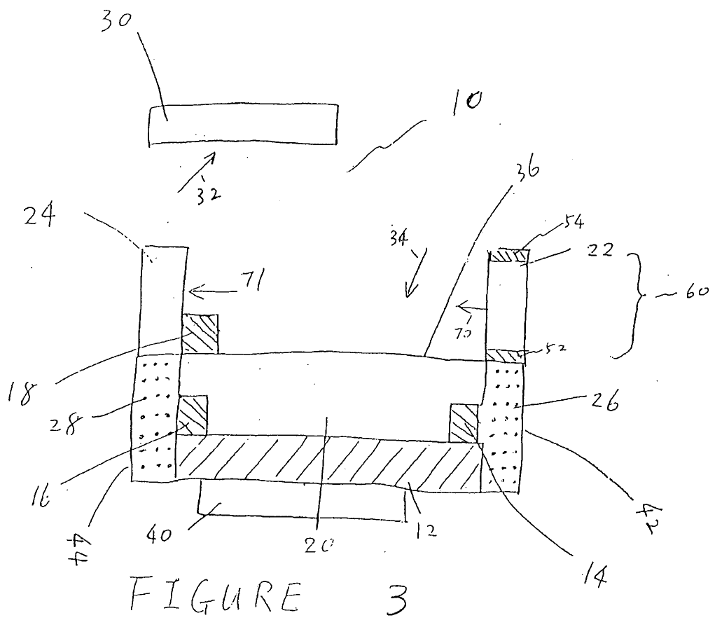

FIG. 3 is a sectional view of a sensor assembly 10 comprised of a substrate 12, a conductor 14, a conductor 16, a conductor 18, a piezoelectric element 20, a source of laser light 60, a photodetector 24, and heat conductors 26 and 28.

The substrate 12 is preferably pure silicon, which, in one embodiment, is single crystal silicon. Processes for making and using single crystal silicon structures are well known. Reference may be had, e.g., to U.S. Pat. No. 6,284,309 (epitaxial silicon waver), U.S. Pat. No. 6,136,630 (single crystal silicon), U.S. Pat. No. 5,912,068 (single crystal silicon), U.S. Pat. No. 5,818,100 (single crystal silicon), U.S. Pat. No. 5,646,073 (single crystal silicon), and the like. The entire disclosure of each of these United States patents is hereby incorporated by reference into this specification. The entire disclosure of this United States patent is hereby incorporated by reference into this specification.

Referring again to FIG. 3, and in the preferred embodiment depicted therein, the substrate 12 generally has a thickness of from about 1 to about 2 millimeters.

In one embodiment, the single-crystal silicon substrate 12 preferably has a <100> orientation. As is known to those skilled in the art, <100> refers to the lattice orientation of the silicon (see, e.g., Column 5 of U.S. Pat. No. 6,329,305). Reference also may be had to a text by S. M. Sze entitled “Physics of Semiconductor Devices,” 2d Edition (Wiley-Interscience, New York, N.Y., 1981). At page 386 of this text, Table 1 indicates that there are three silicon crystal plane orientations, <111>, <110>, and <100>. The <100> orientation is preferred for one embodiment, the <110> orientation is preferred for a second embodiment, and the <111> orientation is preferred for a third embodiment. In any case, the single crystal silicon substrate 12 has only one of such orientations.

Referring again to FIG. 3, aluminum conductors 14 and 16 are grown near the periphery of substrate 12. The structure depicted in Figure may be produced by growing an entire layer of aluminum and then etching away a portion thereof.

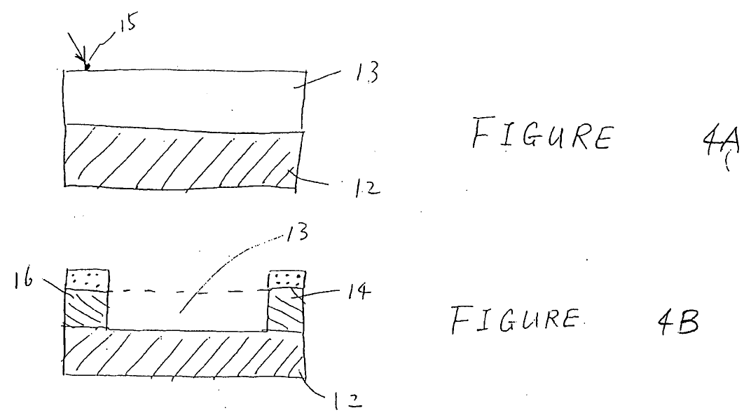

Referring to FIG. 4A, an aluminum layer 13 may be grown on substrate 12, preferably by conventional sputtering techniques. Reference may be had, e.g., to U.S. Pat. No. 5,835,273 (deposition of an aluminum mirror), U.S. Pat. No. 5,711,858 (deposition of aluminum alloy film), U.S. Pat. No. 4,976,839 (aluminum electrode), and the like. The entire disclosure of each of these United States patents is hereby incorporated by reference into this specification.

One may deposit either aluminum or an aluminum alloy, provided that such aluminum material preferably has a certain conductivity. It is preferred that the aluminum conductor 14 have a resistivity of less than about 3 microohms-centimeter. Conductor 16 should have a resistivity of at least 1.5 times as great as the resistivity of conductor 14, and such resistivity is generally less than about 5 microohms-centimters.

One can vary the resistivity of elements 14 and 16 during deposition thereof by preferentially providing a high oxygen content near point 15 so that conductor 16, after it has been formed, will contain more oxide material and have a higher resistivity.

Referring again to FIG. 4A, a layer 13 of aluminum may be deposited onto substrate 12 by reactive sputtering, as described hereinabove; and, during such deposition, selective reaction with oxygen (or other gases) may be caused to occur at specified points (such as point 15) of the aluminum layer being deposited. Thereafter, after the solid layer 13 has been deposited, it can be preferentially etched away.

In one embodiment, and referring again to FIG. 4B, a mask (indicated in dotted line outline) may be deposited onto the layer 13, and thereafter the unmasked deposited aluminum may be etched away with conventional aluminum etching techniques.

Thus, e.g., one may etch the unmasked area with sputtered with argon or hydrogen or oxygen gas, using conventional sputtering technology; as is known to those skilled in the art, etching is the opposite of deposition. Reference may be had, e.g., to U.S. Pat. Nos. 5,851,364, 5,685,960, 6,222,271, 6,194,783, and the like. The entire disclosure of each of these United States patents is hereby incorporated by reference into this specification.

After the conductors 14 and 16 have been integrally formed with substrate 12, a piezoelectric material 20 is deposited onto the substrate 12/conductors/14-16 assembly by sputtering. In one preferred embodiment, the piezoelectric material 20 is piezoelectric aluminum nitride.

In one aspect of this embodiment, after conductors 14 and 16 have been formed by sputtering/etching, aluminum nitride is preferably formed by sputtering an aluminum target 30 with nitrogen gas directed in the direction of arrows 32 and/or 34.

In one embodiment, the aluminum nitride layer 20 (see FIG. 3) has a preferred <002> orientation. Means for producing aluminum nitride with such <002> orientation are well known to those skilled in the art. Reference may be had, e.g., to U.S. Pat. No. 6,329,305, which, at Column 1, refers to “An example of an advantageous film orientation is <002> of AIN perpendicular to the substrate.” This patent claims: “A method for fabricating an electronic device having a piezoelectric material deposited on at least one metal layer, the method comprising depositing the at least one metal layer on a substrate and depositing the piezoelectric material on the metal layer, wherein the texture of the piezoelectric material is determined by controlling the surface roughness of the metal layer.” The entire disclosure of this United States patent is hereby incorporated by reference into this specification.

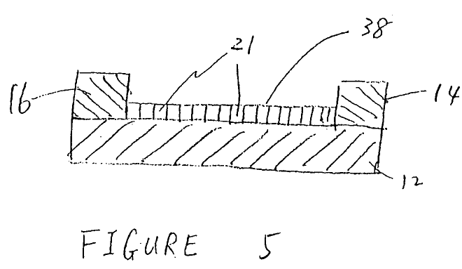

FIG. 5 is a schematic representation of a film orientation <002> of aluminum nitride, with respect to substrate 12 and/or film plane 38. Referring to FIG. 3, and in the preferred embodiment depicted therein, it will be seen that columnized growths 21 preferably form such aluminum nitride 20. These columnar growths 21 are substantially perpendicular to the substrate 12. Reference may be had, e.g., to R. F. Bunshah's “Deposition Technologies for Films and Coatings” (Noyes Publications, Park Ridge, N.J., 1982). At page 131 of such text, columnar grains in a condensate are shown in FIG. 4.36.

Referring again to FIG. 3, the <002> aluminum nitride is deposited up to level 36 so that layer 20 has a thickness of about 1 micron. Thereafter, layers 26 and 28 are deposited onto the assembly by sputtering.

These layers 26 and 28 also preferably consist essentially of aluminum nitride, but they preferably are not piezoelectric. One may obtain such non-piezoelectric properties (or lack thereof) by conventional sputtering techniques in which the aluminum nitride is deposited but no alignment thereof is inducted.

Thus, e.g., in the embodiment depicted in FIG. 3 one may dispose a heater 40 beneath the substrate 12 and operate such heater when one is depositing the aluminum nitride material with the <002> orientation (with respect to substrate 12 and/or film plane 38) and the piezoelectric properties. Thereafter, one may turn the heater 40 off while depositing the aluminum nitride layers 26/28, neither of which has piezoelectric properties or the <002> orientation with respect to film planes 42/44.

However, although the layers 26 and 28 do not have piezoelectric properties, they do have certain heat conductivity properties. It is preferred that each of layers 26 and 28 have a heat conductance of about 2 Watt/degrees Centigrade/centimeter and a resistivity of about 1×10¹⁶ ohm-centimeter. As will be apparent, each of layers 26 and 28 are heat conductors.

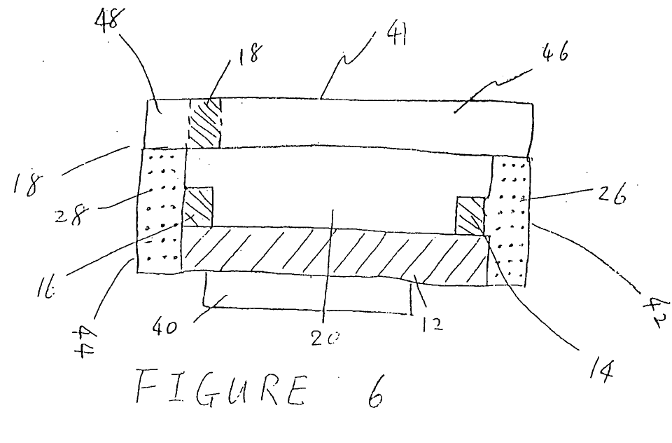

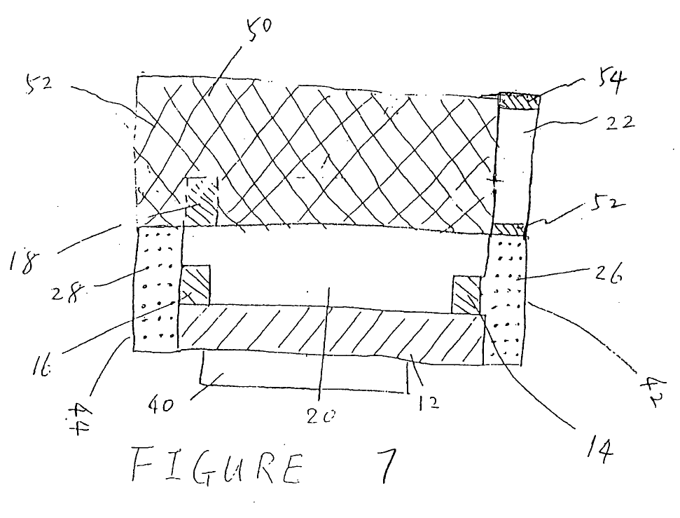

FIG. 6 is a schematic of a preferred process similar to that depicted in FIG. 3. Referring to FIG. 3, in the manner described elsewhere in this specification, a layer 41 of aluminum material is deposited by sputtering (also see FIG. 4A). Thereafter, in the manner depicted in FIG. 4B, portions 46 and 48 are etched away by reactive sputtering to leave the integrally formed conductive layer 18. Thereafter, another layer of aluminum nitride is deposited, as is illustrated in FIG. 7.

Referring to FIG. 7, a layer of aluminum nitride 50 is deposited by sputtering. This is preferably done only after conductor 52 is deposited in the manner described hereinabove; and, after it has been done, conductor 54 is formed in the manner described hereinabove.

The aluminum nitride material that forms layer 50 preferably has a direct energy band gap of 6.2 electron volts, a heat conductance of about 2 Watt/degrees-Centigrade/centimeter and a resistivity of about 1×10¹⁶ ohm-centimeter. This material also is substantially pure aluminum nitride; and, consequently, it functions as a laser material after it has been formed into the structure depicted in FIG. 7, wherein the section that is shown as being crossed-out is etched away in the manner described elsewhere.

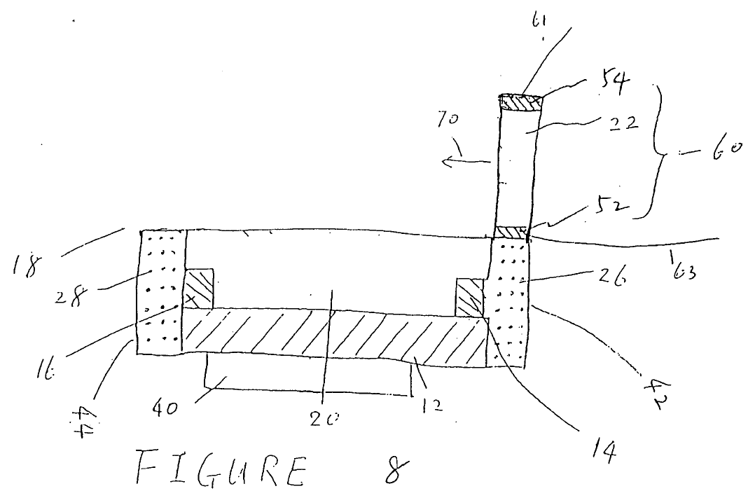

In this embodiment, the final desired structure is depicted in FIG. 8. In another embodiment, shown in FIG. 3, a photodetector layer 24 is deposited with material which, in one apsect, is substantially the same as material 22. In this aspect, both structure 22 and 24 are preferably simultaneously formed by etching. In this aspect, two aluminum conductors (not shown) are formed in the same manner as conductors 52 and 54 (see FIG. 8), but are integrally connected to device 24.

Referring to FIG. 8, when the laser device 60 receives electrical current via lines 61 and 63, laser light is emitted in the direction of arrow 70.

Referring to FIG. 3, when photonic energy 71 impacts photodetector 24, the electrical properties of photodetector 24 are changed, whereby a signal is produced from such sensor.

### Preparation of a Doped Aluminum Nitride Assembly

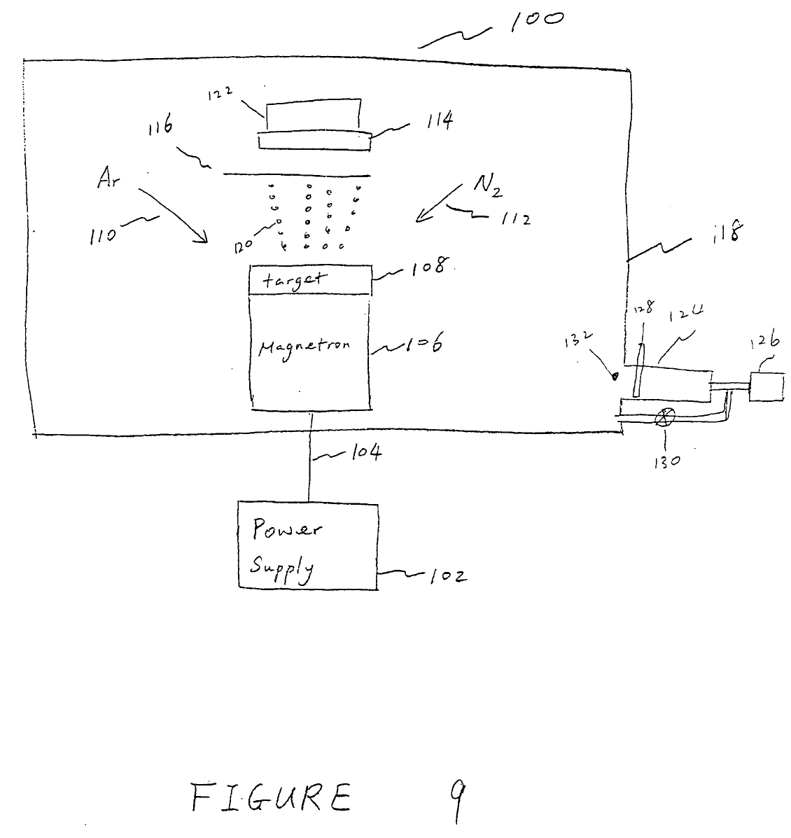

The system depicted in FIG. 9 may be used to prepare an assembly comprised of moieties A, B, and C (see FIG. 1). FIG. 9 will be described hereinafter with reference to one of the preferred ABC moieties, i.e., aluminum nitride doped with magnesium.

FIG. 9 is a schematic of a deposition system 100 comprised of a power supply 102 operatively connected via line 104 to a magnetron 106. Disposed on top of magnetron 106 is a target 108. The target 108 is contacted by gas 110 and gas 112, which cause sputtering of the target 108. The material so sputtered contacts substrate 114 when allowed to do so by the absence of shutter 116.

In one preferred embodiment, the target 108 is mixture of aluminum and magnesium atoms in a molar ratio of from about 0.05 to about 0.5 Mg/(Al+Mg). In one aspect of this embodiment, the ratio of Mg/(Al+Mg) is from about 0.08 to about 0.12. These targets are commercially available and are custom made by companies such as, e.g., Kurt Lasker and Company of Pittsburgh, Pa.

The power supply 110 preferably provides pulsed direct current. Generally, power supply 110 provides power in excess of 300 watts, preferably in excess of 500 watts, and more preferably in excess of 1,000 watts. In one embodiment, the power supplied by power supply 110 is from about 1800 to about 2500 watts.

The power supply preferably provides rectangular-shaped pulses with a duration (pulse width) of from about 10 nanoseconds to about 100 nanoseconds. In one embodiment, the pulse width is from about 20 to about 40 nanoseconds.

In between adjacent pulses, substantially no power is delivered. The time between adjacent pulses is generally from about 1 microsecond to about 10 microseconds and is generally at least 100 times greater than the pulse width. In one embodiment, repetition rate of the rectangular pulses is preferably about 150 kilohertz.

One may use a conventional pulsed d.c. power supply. Thus, e.g., one may purchase such a power supply from Advanced Energy Company of Colorado, and/or from ENI Company of Rochester, N.Y.

The pulsed d.c. power from power supply 102 is delivered to a magnetron 106, that creates an electromagnetic field near target 108. In one embodiment, a magnetic field has a magnetic flux density of from about 0.01 Tesla to about 0.1 Tesla.

As will be apparent, because the energy provided to magnetron 106 comprises intermittent pulses, the resulting magnetic fields produced by magnetron 106 will also be intermittent. Without wishing to be bound to any particular theory, applicants believe that the use of such intermittent electromagnetic energy yields better results than those produced by continuous radio-frequency energy.

Referring again to FIG. 9, it will be seen that the process depicted preferably is conducted within a vacuum chamber 118 in which the base pressure is from about 1×10⁻⁸ Torr to about 0.000005 Torr. In one embodiment, the base pressure is from about 0.000001 to about 0.000003 Torr.

The temperature in the vacuum chamber 118 generally is ambient temperature prior to the time sputtering occurs.

In the embodiment illustrated in FIG. 9, argon gas is fed via line 110, and nitrogen gas is fed via line 112 so that both impact target 108, preferably in an ionized state.

The argon gas, and the nitrogen gas, are fed at flow rates such that the flow rate of the argon gas divided by the flow rate of the nitrogen gas is from about 0.6 to about 1.2. In one aspect of this embodiment, such ratio of argon to nitrogen is from about 0.8 to about 0.95. Thus, for example, the flow rate of the argon may be 20 standard cubic centimeters per minute, and the flow rate of the nitrogen may be 23 standard cubic feet per minute.

The argon gas, and the nitrogen gas, contact a target 108 that is immersed in an electromagnetic field. This field tends to ionize the argon and the nitrogen, providing ionized species of both gases. It is such ionized species that bombard target 108.

In one embodiment, target 108 may be, e.g., pure aluminum. In one preferred embodiment, however, target 108 is aluminum doped with minor amounts of one or more of the aforementioned moieties B.

In the latter embodiment, the moieties B are preferably present in a concentration of from about 1 to about 40 molar percent, by total moles of aluminum and moieties B. It is preferred to use from about 5 to about 30 molar percent of such moieties B.

The ionized argon gas, and the ionized nitrogen gas, after impacting the target 108, creates a multiplicity of sputtered particles 120. In the embodiment illustrated in FIG. 9, the shutter 116 prevents the sputtered particles from contacting substrate 114.

When the shutter 116 is removed, however, the sputtered particles 120 can contact and coat the substrate 114.

In one embodiment, illustrated in FIG. 9, the temperature of substrate 114 is controlled by controller 122, that can heat the substrate (by means such as a conduction heater or an infrared heater) and/or cool the substrate (by means such as liquid nitrogen or water).

The sputtering operation increases the pressure within the region of the sputtered particles 120. In general, the pressure within the area of the sputtered particles 120 is at least 100 times, and preferably 1000 times, greater than the base pressure.

Referring again to FIG. 9, a cryo pump 124 is preferably used to maintain the base pressure within vacuum chamber. In the embodiment depicted, a mechanical pump (dry pump) 126 is operatively connected to the cryo pump 124. Atmosphere from chamber 118 is removed by dry pump 126 at the beginning of the evacuation. At some point, shutter 128 is removed and allows cryo pump to continue the evacuation. A valve 130 controls the flow of atmosphere to dry pump 126 so that it is only open at the beginning of the evacuation.

It is preferred to utilize a substantially constant pumping speed for cryo pump 124, i.e., to maintain a constant outflow of gases through the cryo pump. This may be accomplished by sensing the gas outflow via sensor 132 and, as appropriate, varying the extent to which the shutter 128 is open or partially closed.

Without wishing to be bound to any particular theory, applicants believe that the use of a substantially constant gas outflow rate insures a substantially constant deposition of sputtered nitrides.

Referring again to FIG. 9, it is preferred to clean the substrate 114 prior to the time it is utilized in the process. Thus, e.g., one may use detergent to clean any grease or oil or fingerprints off the surface of the substrate. Thereafter, one may use an organic solvent such as acetone, isopropryl alcohol, toluene, etc.

In one embodiment, the cleaned substrate is presputtered by suppressing sputtering of the target 108 and sputtering the surface of the substrate 114.

As will be apparent to those skilled in the art, the devices of FIGS. 3 and 8 are capable of measuring the mass of a chemical/biological matter as well as its optical absorption properties. These devices, furthermore, because of the use of a heater 16, and the heat conductive layers 26/28, and one or more thermal sensors (not shown) can maintain themselves at a substantially constant temperature.

It is to be understood that the aforementioned description is illustrative only and that changes can be made in the apparatus, in the ingredients and their proportions, and in the sequence of combinations and process steps, as well as in other aspects of the invention discussed herein, without departing from the scope of the invention.

We claim:

1. A nanoelectrical material with an average particle size of less than 100 nanometers, a surface area to volume ratio of from about 0.1 to about 0.05 l/nanometer, and a relative dielectric constant of less than about 1.5.

2. A coated substrate, wherein said substrate is coated with nanoelectrical material with an average particle size of less than 100 nanometers, a surface area to volume ratio of from about 0.1 to about 0.05 l/nanometer, and a relative dielectric constant of less than about 1.5.

3. The coated substrate as recited in claim 2, wherein said coating has a thickness of from about 10 nanometers to about 2 micrometers.

4. The coated substrate as recited in claim 2, wherein said coating has a thickness of from about 100 nanometers to about 1 micrometer.

5. The coated substrate as recited in claim 4, wherein said nanoelectical material is consists of a mixture of aluminum nitride doped with magnesium.

6. The coated substrate as recited in claim 5, wherein from about 5 to about 30 weight percent of magnesium is present in said coating, by total of such coating.
